(19) United States
(12) Patent Application Publication
(10) Pub. No.: US 2023/0021795 A1
(43) Pub. Date: Jan. 26, 2023

(54) METHODS OF PREPARING REGIOREGULAR CONJUGATED POLYMERS

(71) Applicant: THE UNIVERSITY OF CHICAGO, Chicago, IL (US)

(72) Inventors: Xunshan LIU, Chicago, IL (US); Luping YU, Chicago, IL (US); Valerii SHARAPOV, Chicago, IL (US)

(21) Appl. No.: 17/778,550

(22) PCT Filed: Nov. 11, 2020
(86) PCT No.: PCT/US2020/059992

§ 371 Date: May 20, 2022

Related U.S. Application Data
(60) Provisional application No. 62/938,632, filed on Nov. 21, 2019.

(51) Int. Cl. C08G 61/12; G03F 7/11

(52) U.S. Cl. CPC C08G 61/126; G03F 7/11; C08G 2261/18; C08G 2261/11; C08G 2261/228; C08G 2261/3243; C08G 2261/1426

(57) ABSTRACT

Described herein is a novel polymerization method that is useful for synthesizing regioregular conjugated polymers from electron rich aromatic monomers and oligomers of electron rich aromatic monomers.

### CROSS-REFERENCE TO RELATED APPLICATIONS

This application claims priority to U.S. Provisional Application Ser. No. 62/938,632, filed on Nov. 21, 2019, the content of which is hereby incorporated by reference in its entirety.

### GOVERNMENT SUPPORT CLAUSE

This invention was made with government support under grant numbers CHE-1802274 and DMR-1420709 awarded by the National Science Foundation, and grant number DE-ACO2-06CH11357 awarded by the Department of Energy. The government has certain rights in the invention.

### FIELD OF INVENTION

Described herein is a novel polymerization method that is useful for synthesizing regioregular conjugated polymers from electron rich aromatic monomers and oligomers of electron rich aromatic monomers.

### BACKGROUND

Conjugated polymers are characterized by an electronically delocalized i-conjugated backbone. This broad class of materials has attracted considerable attention from both industrial and academic research communities. Higher levels of morphological order in the solid state are more easily achieved when there is translational symmetry between repeat units, or substructures that comprise a number of repeat units, along the backbone vector. Regeoregular polymers normally show higher levels of crystallinity, stronger aggregation effects, larger charge carrier mobilities and ordered nanostructures. These advantages are very important for improving the performance related applications such as organic field effects transistors and organic solar cells.

Early contributions in this field demonstrated the preparation of regioregular polymers through transition metal catalysed methods. The polymerization sequence is achieved by using transition metal initiators, such as Ni(dppp)Cl₂, through a mechanism involving oxidative addition, transmetalation, and reductive elimination. Under certain conditions, the reductive elimination step can be controlled to avoid detachment of the growing chain from the metal centre, thus leading to a chain-growth, living polymerization sequence. An alternative strategy to achieve structurally uniform backbones is to react two symmetrical monomer precursors in the polymerization reaction.

Regioregular conjugated polymers can be synthesized via photoinduced polymerization in solid state according to the methods described herein. Detailed studies of the reaction lead to the proposal of an unusual mechanism, a photoinduced “chain-like” polycondensation reaction. This photoinduced chain-like polycondensation reaction is novel and could have broad applications in the syntheses of other polymers.

Compared to conventional cationic polymerizations, the method described herein includes several advantages. First, it can be induced by ambient room light and ambient room temperature. These moderate reaction conditions are important for practical applications. Second, the product is a regioregular polymer, which is very crucial for electrical properties but very difficult to achieve with conventional methods. Finally, the reactant compounds for this cationic polymerization demonstrated herein are aromatic molecules, which have not been studied with conventional methods. The scope of the reactant compound can be extended to any electron rich aromatic monomers or oligomers of any electron rich aromatic monomers.

The results of the present disclosure have important implications in both the synthesis of conjugated polymers and cationic chain growth polymerization mechanisms involving aromatic monomers. These findings, including the newly discovered polymerization mechanism, may pave the way to the exploration of many interesting applications including as a patterning material, polymer binders for Lithium/Si batteries, and cross-linked polymers as membranes.

### BRIEF DESCRIPTION OF THE DISCLOSURE

In one aspect, provided herein is a method of preparing a regioregular conjugated polymer, the method comprising:

introducing a compound, wherein the compound is a monohalogenated electron rich aromatic monomer;

exposing the compound to light; and

polymerizing the compound.

In another aspect, provided herein is a method of preparing a regioregular conjugated polymer, the method comprising:

introducing a compound, wherein the compound is an oligomer of a monohalogenated electron rich aromatic monomer;

exposing the compound to light; and

polymerizing the compound;

wherein the regioregular conjugated polymer is crosslinked.

In yet another aspect, provided herein is a method of patterning, the method comprising

spin coating on a surface a compound selected from the group consisting of a monohalogenated electron rich aromatic monomer and an oligomer of a monohalogenated electron rich aromatic monomer;

covering the surface with a pattern mask;

exposing the pattern mask to light; and

polymerizing the compound not covered by the pattern mask.

### BRIEF DESCRIPTION OF THE DRAWINGS

FIG. 1 is a graphical depiction of TGA curves of PTT-Ni and PTT-L polymers at a scan rate of 5° C./min.

FIG. 2 is a graphical depiction of a MALDI-TOF mass spectrum of PTT-L.

FIG. 3 is a zoomed-in spectrum of FIG. 2 around peak 1813.7.

FIG. 4 is a graphical depiction of Vis-NIR absorption spectra of PTT-Ni and PTT-L polymers in CHCl₃.

FIG. 5 is a graphical depiction of Vis-NIR absorption spectra of PTT-Ni and PTT-L polymer films.

FIG. 6 is a graphical depiction of the FTIR spectra of PTT-Ni and PTT-L polymers.

FIG. 7 is a graphical depiction of the cyclic voltammograms of PTT-Ni and PTT-L polymers in CH₃CN/0.1 M Bu₄NPF₆ at 100 mV/s.

FIG. 8A is a graphical depiction of I-V curves of hole-only and electron-only devices for PTT-L polymers.

FIG. 8B is a graphical depiction of I-V curves of hole-only and electron-only devices for PTT-Ni polymers

FIG. 9 is a graphical depiction of the optimized geometry of monomer M1 and calculated Mulliken charge distribution.

FIG. 10 is a graphical depiction of the proposed reaction scheme. This proposed reaction scheme does not bind the present disclosure to any particular theory.

FIG. 11 is a graphical depiction of an exemplary embodiment of patterning through the polymerization methods of the present disclosure. A pattern achieved by polymerization of monomer M1 is on the left and the utilized laser cut mask is on the right.

FIG. 12 is a graphical depiction of GIWAXS patterns of PTT-L and PTT-Ni films (top row) and 1D-linecuts in an out-of-plane (q_{z}) direction and an in-plane (q_{xy}) direction (bottom row), in accordance with the present disclosure.

FIG. 13 is a graphical depiction of a mass spectrum obtained to investigate potential side products of reactions in accordance with the present disclosure.

### DETAILED DESCRIPTION OF THE DISCLOSURE

As used herein, the terms “comprises,” “comprising,” “includes,” “including,” “has,” “having,” “contains”, “containing,” “characterized by” or any other variation thereof, are intended to cover a non-exclusive inclusion, subject to any limitation explicitly indicated. For example, a composition, mixture, process or method that comprises a list of elements is not necessarily limited to only those elements but may include other elements not expressly listed or inherent to such composition, mixture, process or method.

The transitional phrase “consisting of” excludes any element, step, or ingredient not specified. If in the claim, such would close the claim to the inclusion of materials other than those recited except for impurities ordinarily associated therewith. When the phrase “consisting of” appears in a clause of the body of a claim, rather than immediately following the preamble, it limits only the element set forth in that clause; other elements are not excluded from the claim as a whole.

The transitional phrase “consisting essentially of” is used to define a composition or method that includes materials, steps, features, components, or elements, in addition to those literally disclosed, provided that these additional materials, steps, features, components, or elements do not materially affect the basic and novel characteristic(s) of the claimed invention. The term “consisting essentially of” occupies a middle ground between “comprising” and “consisting of”.

Where an invention or a portion thereof is defined with an open-ended term such as “comprising,” it should be readily understood that (unless otherwise stated) the description should be interpreted to also describe such an invention using the terms “consisting essentially of” or “consisting of”.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, the indefinite articles “a” and “an” preceding an element or component of the invention are intended to be nonrestrictive regarding the number of instances (i.e. occurrences) of the element or component. Therefore “a” or “an” should be read to include one or at least one, and the singular word form of the element or component also includes the plural unless the number is obviously meant to be singular.

As used herein, the term “about” means plus or minus 10% of the value.

When a group contains a substituent which can be hydrogen, for example R⁴, then, when this substituent is taken as hydrogen, it is recognized that this is equivalent to said group being unsubstituted.

The term “halogen”, either alone or in compound words such as “halogenated alkyl”, includes fluorine, chlorine, bromine or iodine. Further, when used in compound words such as “halogenated alkyl”, said alkyl may be partially or fully substituted with halogen atoms which may be the same or different.

The term “alkyl” includes, without limitation, a functional group comprising straight-chain or branched alkyl.

The term “ester” includes, without limitation, a functional group comprising an ester bond (—C(═O)—O—).

The term “ether” includes, without limitation, a functional group comprising an ether bond (—C—O—C—).

The term “ketone” includes, without limitation, a functional group comprising a carbonyl bond (—C(═O)—).

The term “cyano” includes, without limitation, a functional group comprising a nitrile bond (—C≡N).

The term “thiol” includes, without limitation, a functional group comprising a thiol bond (—S—H).

The term “sulfonyl” includes, without limitation, a functional group comprising a sulfonyl bond (—S(═O)(═O)—).

Described herein is a method of preparing regioregular conjugated polymers. Without being bound to theory, the method is believed to occur via a photoinduced chain-like polycondensation reaction. This photoinduced chain-like polycondensation reaction is novel and could have broad applications in the syntheses of other polymers.

A wide variety of regioregular conjugated polymers may be prepared according to the methods of the present disclosure. In some embodiments, the regioregular conjugated polymer is selected from the group consisting of regioregular polythienothiophene and regioregular polyazulene. In some embodiments, the regioregular conjugated polymer is crosslinked. In some embodiments, the properties of the regioregular conjugated polymers can be tuned based on the substituents on the monomeric and/or oligomeric core. The monomers must contain a monohalogenated electron rich core which will form the backbones of the polymers. These polymers should have narrow energy band gap and broad light absorption. In some embodiments, the regioregular conjugated polymers have an ultralow optical band gap.

In some embodiments, the regioregular conjugated polymers are prepared from a compound selected from the group consisting of a monohalogenated electron rich aromatic monomer, an oligomer of a monohalogenated electron rich aromatic monomer, and combinations thereof. In some embodiments, the regioregular conjugated polymers are prepared from a compound selected from the group consisting of a monohalogenated electron rich aromatic monomer and an oligomer of a monohalogenated electron rich aromatic monomer. In some embodiments, the compound is a solid reactant. In some embodiments, the compound is selected from the group consisting of thienothiophene, a thienothiophene derivative, azulene, and an azulene derivative. In some embodiments, the oligomer of a monohalogenated electron rich aromatic monomer is a dimer or trimer of said monomer. In some embodiments, the monohalogenated electron rich aromatic monomer comprises at least 10 π electrons. In some embodiments, the monohalogenated electron rich aromatic monomer comprises a fused bicyclic aromatic group.

In some embodiments, the regioregular conjugated polymers are prepared from a first compound selected from the group consisting of a monohalogenated electron rich aromatic monomer, an oligomer of a monohalogenated electron rich aromatic monomer, and combinations thereof, and a second compound selected from the group consisting of a monohalogenated electron rich aromatic monomer, an oligomer of a monohalogenated electron rich aromatic monomer, and combinations thereof. In some embodiments, the regioregular conjugated polymers are prepared from a first compound selected from the group consisting of a monohalogenated electron rich aromatic monomer and an oligomer of a monohalogenated electron rich aromatic monomer and a second compound selected from the group consisting of a monohalogenated electron rich aromatic monomer and an oligomer of a monohalogenated electron rich aromatic monomer. In some embodiments, the first compound and second compound are a mixture of a monohalogenated electron rich aromatic monomer and an oligomer of a monohalogenated electron rich aromatic monomer. In some embodiments, the first compound and second compound are a mixture of two different monohalogenated electron rich aromatic monomers. In some embodiments, the first compound and second compound are a mixture of two different oligomers of monohalogenated electron rich aromatic monomers.

In some embodiments, the compound polymerizes upon exposure to light. In some embodiments, the compound polymerizes upon exposure to ambient light. Ambient light includes regular room light and sunlight. In some embodiments, the compound polymerizes upon exposure to UV light. The UV light may be supplied with a low-pressure mercury-vapor lamp, for example. In some embodiments, the compound polymerizes upon exposure to light for a duration in the range of about 1 minute to about 30 minutes. In some embodiments, the compound partially polymerizes upon exposure to light for a duration less than about 1 minute. In some embodiments, the compound continues to polymerize after the light source is removed. In some embodiments, the compound polymerizes after exposure to light without additional reagents.

In some embodiments, the compound polymerizes at a temperature in the range of about 15° C. to about 35° C. In some embodiments, the compound polymerizes at room temperature. In some embodiments, the compound polymerizes at a temperature in the range of about 0° C. to about 15° C. In some embodiments, the compound polymerizes under conditions of conventional refrigeration.

The embodiments of this disclosure include:

Embodiment 1. A method of preparing a regioregular conjugated polymer, the method comprising:

introducing a compound selected from the group consisting of a monohalogenated electron rich aromatic monomer and an oligomer of a monohalogenated electron rich aromatic monomer;

exposing the compound to light; and

polymerizing the compound.

Embodiment 2. The method of embodiment 1, wherein the method step of introducing the compound comprises introducing the compound as a solid reactant.

Embodiment 3. The method of any of embodiments 1-2, wherein the method step of exposing the compound to light comprises exposing the compound to ambient light.

Embodiment 4. The method of any of embodiments 1-3, wherein the method step of exposing the compound to light comprises exposing the compound to UV light.

Embodiment 5. The method of any of embodiments 1-4, wherein the method step of exposing the compound to light comprises exposing the compound to light for a duration in the range of about 1 minute to about 30 minutes.

Embodiment 6. The method of any of embodiments 1-5, wherein the method step of polymerizing the compound comprises polymerizing the compound at a temperature in the range of about 0° C. to about 15° C.

Embodiment 7. The method of any of embodiments 1-6, wherein the method step of polymerizing the compound comprises polymerizing the compound at a temperature in the range of about 15° C. to about 35° C.

Embodiment 8. The method of any of embodiments 1-7, wherein the method step of polymerizing the compound comprises polymerizing the compound in the absence of external reagents.

Embodiment 9. The method of any of embodiments 1-8, wherein the monohalogenated electron rich aromatic monomer comprises at least 10 π electrons.

Embodiment 10. The method of any of embodiments 1-9, wherein the monohalogenated electron rich aromatic monomer comprises a fused bicyclic aromatic group.

Embodiment 11. The method of any of embodiments 1-10, wherein the monohalogenated electron rich aromatic monomer is a compound of Formula I, wherein

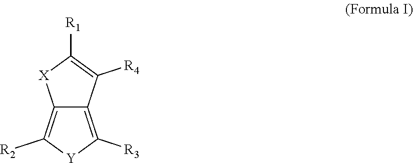

each of X and Y are independently selected from the group consisting of nitrogen, sulfur, phosphorous, and oxygen;
R₁ is selected from the group consisting of alkyl, halogenated alkyl, ester, ether, ketone, cyano, thiol, and sulfonyl;
each of R₂-R₄ is independently selected from the group consisting of hydrogen and halogen;

and

at least one of R₂-R₄ is a halogen.

Embodiment 12. The method of any of embodiments 1-11, wherein the monohalogenated electron rich aromatic monomer is a compound of Formula II, wherein

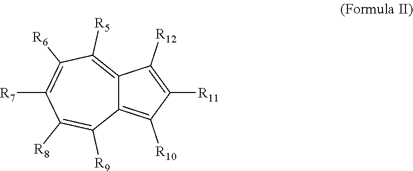

each of R₅-R₁₂ is independently selected from the group consisting of hydrogen and halogen;

and

wherein at least one of R₅-R₁₂ is a halogen.

Embodiment 13. The method of any of embodiments 1-12, wherein the monohalogenated electron rich aromatic monomer is selected from the group consisting of

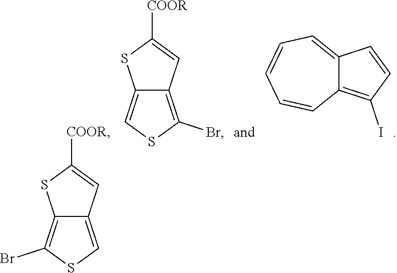

wherein R is selected from the group consisting of linear alkyl and branched alkyl.

Embodiment 14. The method of any of embodiments 1-13, wherein the monohalogenated electron rich aromatic monomer is selected from the group consisting of

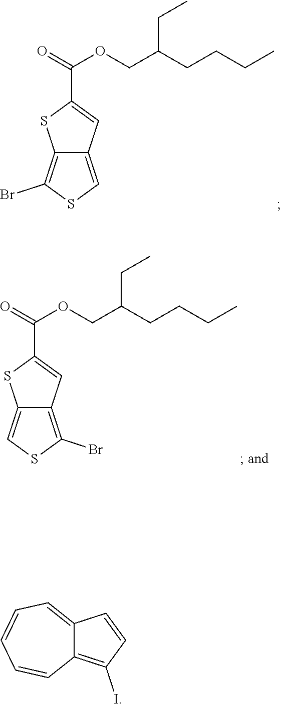 [SMILES: CCCCC(CC)COC(=O)c1cc2csc(Br)c2s1 ; CCCCC(CC)COC(=O)c1cc2c(Br)scc2s1 ; Ic1ccc2cccccc1-2]

Embodiment 15. The method of any of embodiments 1-14, wherein the oligomer of a monohalogenated electron rich aromatic monomer is a dimer or a trimer of the monohalogenated electron rich aromatic monomer.

Embodiment 16. The method of any of embodiments 1-15, wherein the method further comprises introducing a second compound selected from the group consisting of a monohalogenated electron rich aromatic monomer and an oligomer of a monohalogenated electron rich aromatic monomer before the method step of exposing the compound to light.

Embodiment 17. The method of any of embodiments 1-16, wherein the regioregular conjugated polymer is selected from the group consisting of regioregular polythienothiophene and regioregular polyazulene.

Embodiment 18. The method of any of embodiments 1-17, wherein the regioregular conjugated polymer is crosslinked.

Embodiment 19. A method of patterning, the method comprising spin coating on a surface a compound selected from the group consisting of a monohalogenated electron rich aromatic monomer and an oligomer of a monohalogenated electron rich aromatic monomer;

covering the surface with a pattern mask;

exposing the pattern mask to light; and

polymerizing the compound not covered by the pattern mask.

Embodiment 20. The method of claim 19, wherein the method further comprises removing the non-polymerized compound covered by the pattern mask.

### EXAMPLES

Without further elaboration, it is believed that one skilled in the art using the preceding description can utilize the present invention to its fullest extent. The following Examples are, therefore, to be construed as merely illustrative, and not limiting of the disclosure in any way whatsoever.

### Example 1. Sample Monomer

A monobromo-thienothiophene compound M1, 2-ethylhexyl 6-bromothieno[3,4-b]thiophene-2-carboxylate, was prepared as an intermediate in the chemical production of thienothiophene oligomers and was found to exhibit very high sensitivity to light. It surprisingly and easily reacted in solid state without adding any external reagents when exposed to room light. This colorless compound changed into a blue solid upon reaction. Gel Permeation Chromatography studies indicated that the blue solid was a polymer material with molecular weight around 4,500 g/mol and a narrow polydispersity. It was also observed that hydrogen bromide was produced as a side product, which was confirmed by a reaction with a trivinyl compound.

When the alkyl species on the carboxylate group of the base monomer, 6-bromothieno[3,4-b]thiophene-2-carboxylate, is a methyl group, the resulting solid polymerization product is insoluble. However, when an ethylhexyl group is used instead of a methyl group, the resulting solid polymerization product is soluble in organic solvents as chloroform and chlorobenzene.

### Example 2. Photochemical Synthesis of PTT

Monomer M1 (2-ethylhexyl 6-bromothieno[3,4-b]thiophene-2-carboxylate (1.2 g)) was sealed in a transparent glass vial under N₂ protection. The vial was exposed to room light for about ten minutes. Polythienothiophene, PTT-L, was then formed in the vial as a dark blue solid. HBr is believed to be a side product because when the vial was opened, a substantial amount of white gas escaped out. The dark blue solid was well washed with MeOH. The solid was then purified by washing with methanol, acetone, hexanes and chloroform in a Soxhlet extractor for 24 h in sequence. The dark blue polymer was dried from the chloroform fraction by rotary evaporation (Mn: 4475, PDI: 1.17). There was a substantial amount of insoluble solid that could not be extracted out with chloroform. The yield based on the polymers in chloroform was 0.25 g, corresponding to 26%.

Spectroscopic data are as follows: 1H NMR (500 MHz, CDCl3 δ/ppm) 7.85 (br, 1H), 4.27 (br, 2H), 1.66-0.92 (br, 15H). FT-IR: 1456 nm (C—C Stretching vibration). The expected elemental composition calculated for (C₁₅H₁₈O₂S₂)ₙ (%) is as follows: C, 60.78; H, 6.80; S, 21.63. The elemental composition (%) of the produced polymer was found to be as follows: C, 61.27; H, 6.45; S, 19.89, Br, 0.0.

### Comparative Example 1. Chemical Synthesis of PTT

To aid in identifying the polymer structure of PTT-L, a polythienothiophene (PTT) homopolymer (PTT-Ni) was synthesized via a Kumada catalyst-transfer polymerization (KCTP) reaction.

A two-neck round-bottomed flask was heated under reduced pressure and then cooled to room temperature under an N₂ atmosphere. Monomer M (2-ethylhexyl 4,6-dibromothieno[3,4-b]thiophene-2-carboxylate (136 mg, 0.3 mmol)) was placed in the flask. Dry THF (1 mL) was added into the flask via a syringe, and the mixture was stirred at 0° C. Isopropylmagnesium chloride (2.0 M solution in THF, 0.15 mL, 0.3 mmol) was added to the mixture via a syringe, the resultant mixture was stirred at 0° C. for 1 h, and then the flask was moved to an Argon glove box. Ni(dppp)Cl₂ (3.5 mg, 0.0064 mmol, 2.1 mol %) was added to the mixture at room temperature, and then the mixture was stirred at room temperature for 12 h. 5M hydrochloric acid was added and the mixture was extracted with CHCl₃. The organic layer was concentrated under reduced pressure. MeOH was added to the residue. The precipitate was washed well with MeOH and collected as polythienothiophene PTT-Ni, (Mn: 3687, polydispersity (PDI): 1.21) as a dark blue solid (73 mg, 83%).

Spectroscopic data are as follows: 1H NMR (500 MHz, CDCl3 δ/ppm) 8.17-7.41 (br, 1H), 4.29 (br, 2H), 1.67-0.90 (br, 15H). FT-IR: 1436 nm, 1462 nm (C—C Stretching vibration). The expected elemental composition calculated for (C₁₅H₁₈O₂S₂)ₙ (%) is as follows: C, 60.78; H, 6.80; S, 21.63. The elemental composition (%) of the produced polymer was found to be as follows: C, 58.22; H, 5.46; S, 21.49, Br, 0.0.

### Example 3. Polymer Characterization

GPC, NMR and MALDI mass spectroscopic studies confirmed that PTT-Ni and PTT-L exhibit identical spectroscopic features. Furthermore, UV/vis spectroscopic studies indicated that both polymers exhibit strong absorption in NIR region with maximum absorption around 1000 nm and an optical bandgap of 0.73 eV. Thus, it is believed that the resulting polymers have identical structures.

Experimental Details

Characterizations of polymers were performed by using NMR, GPC, TGA, UV-vis-NIR and FTIR. 1H NMR and 13C NMR spectra were recorded on a Bruker DRX-500 spectrometer. Matrix-assisted laser desorption ionization time-of-flight (MALDI-TOF) mass spectra were recorded using a Bruker Ultraflextreme MALDI-TOF mass spectrometer with dithranol as the ionization matrix. Fourier transform infrared (FT-IR) spectra were obtained on Thermo Nicolet iS50 Advanced FT-IR. GC-MS mass spectra were measured with Agilent SQ GC-MS (5977A single quad MS and 7890B GC. Ultravioletvisible-Near IR (UV-vis-NIR) spectra of the polymers were measured on SHIMADZU UV-3600 spectrometer. The elemental analyses of the polymers were performed on an Elementar Vario EL III element analyzer for C, H, Br and S determination. Thermogravimetric analyses (TGA) were performed under nitrogen at a heating rate of 5° C./min using a SHIMADZU TGA-50 analyzer. The average molecular weight and polydispersity index (PDI) of each polymer was determined using Waters 1515 gel permeation chromatography (GPC) analysis with CHCl₃ as eluent and polystyrene as standard. Electrochemical redox potentials were obtained by cyclic voltammetry (CV) using a three-electrode configuration and an electrochemistry workstation (AUTOLAB PGSTAT12). CV was conducted on an electrochemistry workstation with the polymer thin film on a Pt working electrode, Pt as the counter electrode as well, and Ag/AgCl as reference electrode in a 0.1 M tetra-n-butylammonium hexafluorophosphate acetonitrile solution at a scan rate of 50 mV/s.

Hole-only devices were fabricated in a configuration ITO/PEDOT:PSS/active layer/MoO₃/Ag and electron-only devices were ITO/ZnO/active layer/Ca/Al. ITO glasses were ultrasonicated in chloroform, acetone, and propanol-2 for 15 min each and then cleaned in a UV/ozone cleaner for 30 min. For hole-only devices PEDOT:PSS water suspension purchased from HERAEUS was spin coated at 6000 rpm/60 seconds and then annealed under vacuum at 100° C. for 30 min. For electron-only devices ZnO precursor solution of Zn(CH₃COO)₂, 2-aminoethanol and 2-methoxyethanol were spin coated at 4000 rpm/40 seconds and annealed in air at 200° C. for 30 minutes. The active layer was spin coated from chloroform/chlorobenzene solution at 1000 rpm/60 seconds and annealed in a nitrogen glove box at 120° C. for 30 minutes. Top electrodes 8 nm MoO₃/90 nm Ag and 20 nm Ca/80 nm Al were thermally deposited under vacuum (10⁻⁷ — 10⁻⁶ Torr) through a shadow mask. I-V curves of the devices were measured and SCLC region of the curves was fitted with the Gurney-Mott equation:

$$J = \frac{9 ε {ε}_{0} {μ ( V - {V}_{b i} )}^{2}}{8 {L}^{3}} ,$$

where J is current density, ε is the dielectric constant (assumed to be 3), ε₀ is the dielectric permittivity of vacuum, μ, is mobility, V is applied voltage, V_{bi} is built-in voltage, and L is the thickness of the film (measured with atomic force microscopy (AFM)).

Molecular Weight Analysis

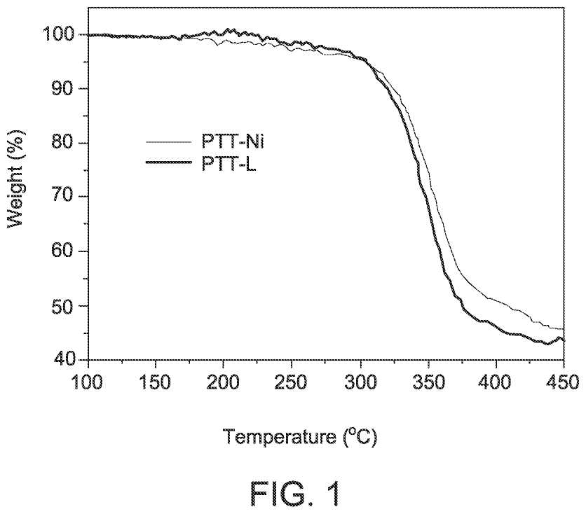

The molecular weights (M_{W}) and polydispersity index (PDI) of PTT-Ni and PTT-L, which are homopolymers, were M_{w}=4.45 kg/mol with PDI=1.21 for PTT-Ni and M_{w}=5.23 kg/mol with PDI=1.17 for PTT-L as determined by GPC (see Table 1). The thermal properties of the polymers were determined by TGA under nitrogen atmosphere at a heating rate of 5° C./min. The two homopolymers (PTT-Ni and PTT-L) have good thermal stability with onset decomposition temperatures (Td) corresponding to 5% weight loss at 300° C. and 303° C., respectively (see FIG. 1).

TABLE 1
Polymerization results and thermal properties.

| Polymer | Yield (%) | Mₙ (kg/mol) | M_{w} (kg/mol)^{a} | PDI | T_{d} (° C.)^{b} |
|---|---|---|---|---|---|
| PTT-Ni | 83 | 3.68 | 4.45 | 1.21 | 300 |
| PTT-L | 92 | 4.48 | 5.23 | 1.17 | 303 |

^{a}Determined by GPC in CHCl₃ based on polystyrene standards.
^{b}Decomposition temperature, determined by TGA in nitrogen, based on 5% weight loss.

Terminal Group Analysis

MALDI-TOF spectrometry was used to measure the molecular weights of the polymers and further analyze the terminal groups. It is believed that PTT-L is terminated with two bromine atoms immediately after reaction. However, the mass spectra did not show the existence of two bromine atoms. These results were also confirmed by elemental analysis of resulting polymers.

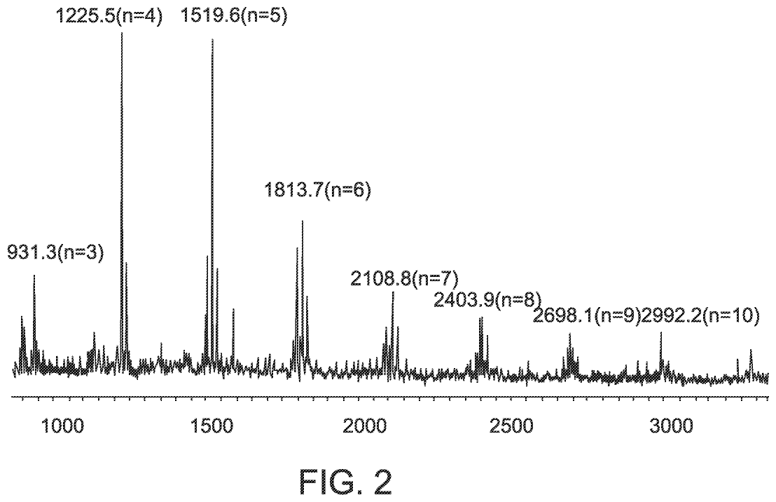

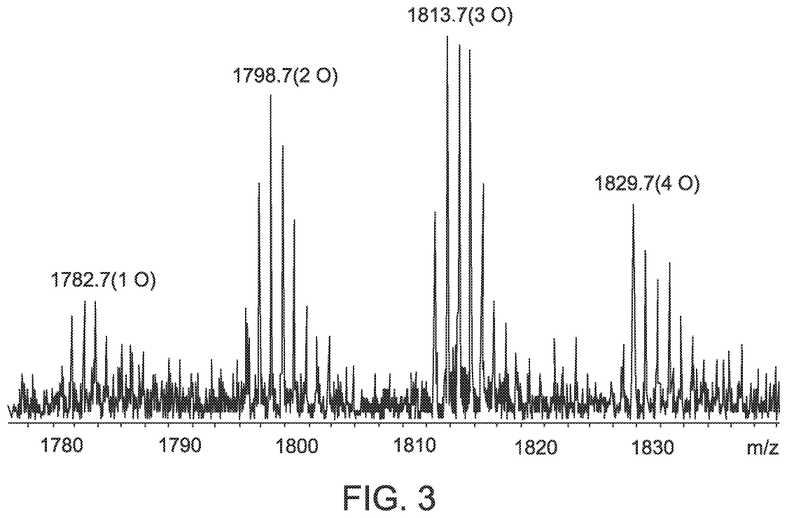

FIG. 2 shows the mass spectrum of PTT-L, in which the molecular weight difference of each peak is about 294, which is the molecular weight of a thienothiophene (TT) unit. For instance, the peak 1225 means a polymer with 4 TT units, which are terminated with one —OH and one —O₂H group. Similarly, 1519 stands for 5 TT units, 1813 stands for 6 TT units, and so on. For further understanding, a zoomed spectrum of the 1813 peak is showed in FIG. 3. Four groups of peaks with multiple isotope peaks are observed. The difference between each group peaks amounts to 16 Daltons, standing for different amounts of 0 atoms at the terminals of the polymers. For instance, the peak 1812 means that there is one O atom, 1797 means 2 O atoms, 1813 means 3 O atoms, and 1830 means 4 O atoms. All the peaks in FIG. 2, exhibit the same trend as the 1813 peak. Accordingly, it is believed that the C—Br bond of the polymer chain terminals are cleaved when the polymer is exposed to light and a polymer radical is formed. Unlike small molecules, the newly formed radicals are difficult to recombine. They tend to react with O₂ from the air to form —OH or —O₂H groups, consistent with the results from the MALDI-TOF mass spectra.

Optical Properties

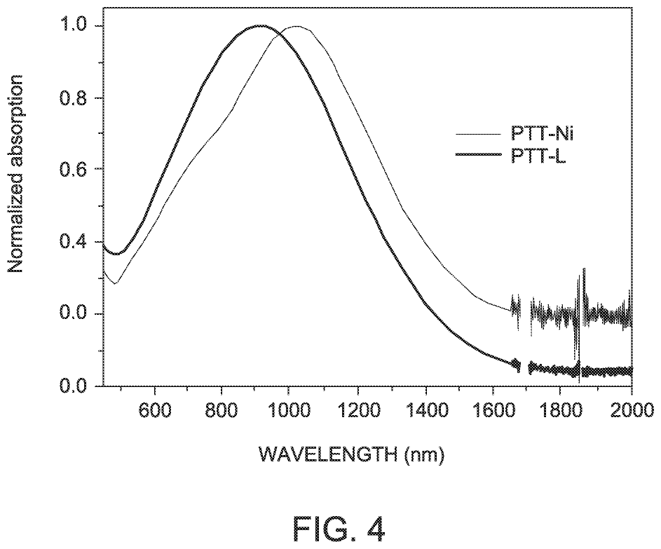

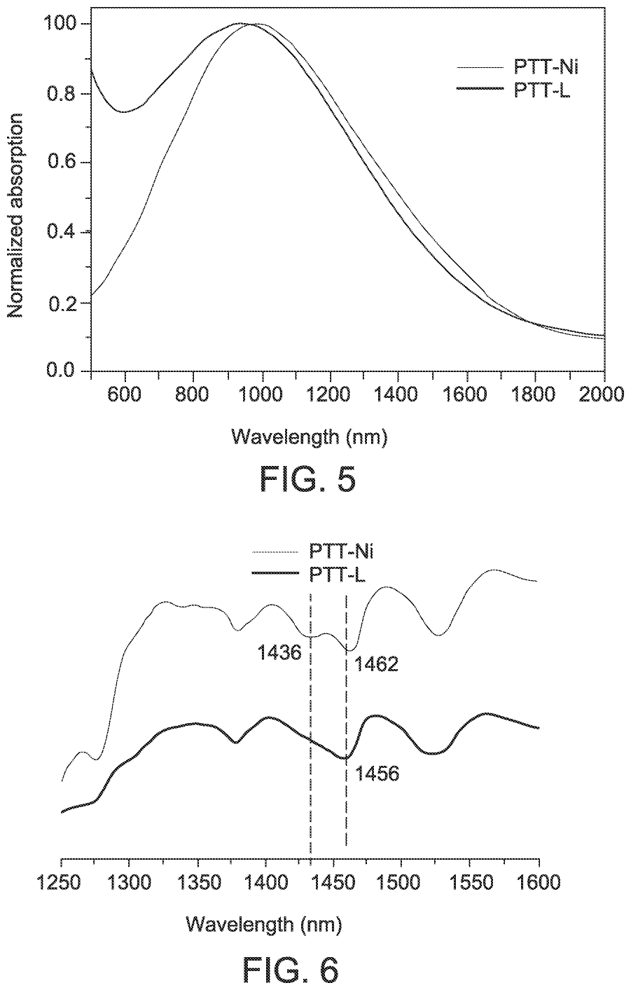

The photophysical properties of the two polymers (PTT-Ni and PTT-L) were investigated by employing UV-Vis-NIR and FTIR spectroscopy. The key physical properties are summarized Table 2. Both of the polymers show a very broad absorption in the visible-NIR region, from about 500 nm to 1700 nm (FIG. 4). PTT-Ni and PTT-L exhibit their absorption maximums at 1017 nm and 910 nm, respectively. It is believed that the difference is due to the differences in regioregularity between the polymers. While the polymer PTT-Ni is a regiorandom polymer because the two bromine atoms of its monomer (M) have no specificity for the Kumada coupling reaction, the PTT-L is a head-tail regioregular polymer. Absorption spectra for thin films are broadened (FIG. 5). Surprisingly, the absorption peak for PTT-Ni is blue-shifted compared to its solution spectrum, while the absorption peak for PTT-L is red-shifted compared to its solution spectrum. This observation is probably due to different aggregation types. The optical band gaps (E_{g}^{opt}) of films comprising the polymers were found to be 0.73 eV for PTT-Ni and 0.76 eV for PTT-L.

The differences in regioregularity of polymers were reflected in a slight difference between their FTIR spectra (see FIG. 6). PTT-L showed only one peak at 1456 nm, however, PTT-Ni shows two peaks (1462 nm and 1436 nm). This observation is consistent with the fact that the PTT-L has only one conformation (head-to-tail), while the PTT-Ni has two or more conformations (head-to-tail, head to head, and/or tail-to-tail).

TABLE 2
Optical and electrochemical properties.

| | Solution | Film | Film | | | | |
|---|---|---|---|---|---|---|---|
| | λ_{s,max} | λ_{f,max} | λ_{edge} | | | | |
| | (nm)^{a} | (nm) | (nm) | E_{g}^{opt} | HOMO | LUMO | E_{g}^{ec} |
| Polymers | Abs. | Abs. | Abs. | (eV)^{b} | (eV) | (eV) | (eV) |
| PTT-Ni | 1017 | 982 | 1692 | 0.73 | −5.00 | −3.75 | 1.25 |
| PTT-L | 910 | 948 | 1632 | 0.76 | −5.10 | −3.67 | 1.43 |

^{a}measured in chloroform solution.
^{b}band gap estimated from the optical absorption band edge of the films.

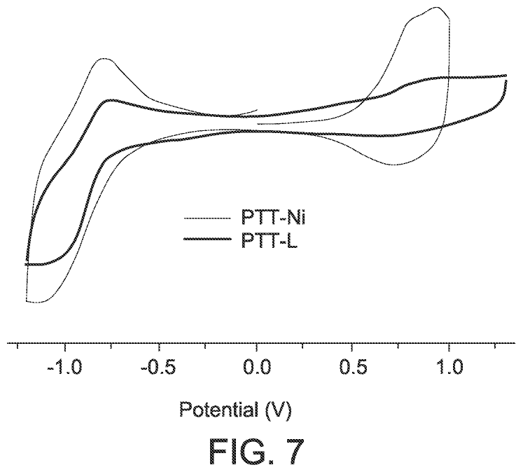

The electrochemical behaviors of PTT-Ni and PTT-L were investigated by cyclic voltammetry (CV). The corresponding CV curves and data (FIG. 7 and Table 2) indicated that these polymers are electroactive. The redox potentials were referenced to the ferrocene/ferrocenium redox couple (Fc/Fc⁺). The redox potential of ferrocene is 0.35 V vs SCE. The redox potential of Fc/Fc⁺ was assumed an absolute energy level of 4.8 eV to vacuum and the HOMO/LUMO energy levels and electrochemical energy gaps (E_{g}^{ec}) of the polymers were calculated according to the following equations:

HOMO=−e(Eₒₓ+4.45) (eV);

LUMO=−e(E_{red}+4.45) (eV); and

E_{g}^{ec}=e(Eₒₓ−E_{red}) (eV).

The onset potentials for oxidation (Eₒₓ) were calculated as 0.55 and 0.65 V for PTT-Ni and PTT-L, respectively, corresponding to the HOMO energy levels of PTT-Ni and PTT-L at −5.00 eV and −5.10 eV, respectively. The LUMO energy levels of PTT-Ni and PTT-L were calculated as −3.75 and −3.67 eV, respectively, indicating low band gaps at 1.25 eV and 1.43 eV, respectively. The low band gaps are in good agreements with their broad absorption in the Visible-NIR region.

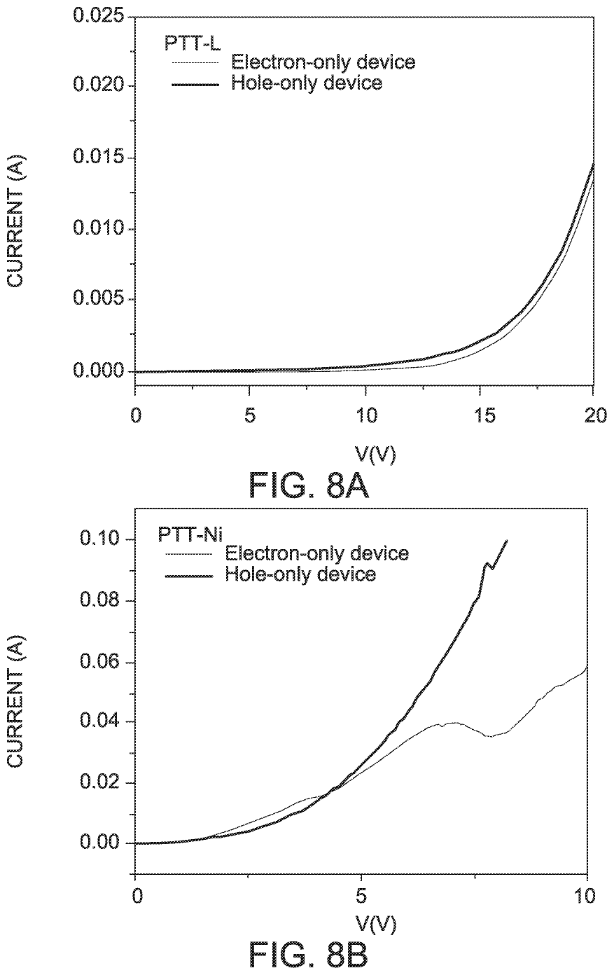

Space-charge limited carrier (SCLC) mobilities of hole-only and electron-only devices were measured to investigate the electrical properties of both polymers. Results are shown in FIG. 8A and FIG. 8B. It was found that the PTT-Ni exhibits hole and electron mobilities of (1.2±0.4)×10⁻⁴ cm²V⁻¹s⁻¹ and (4.2±1.6)×10⁻⁵ cm²V⁻¹s⁻¹ respectively. PTT-L was found to exhibit higher mobilities of (2.7±1.7)×10-4 cm²V⁻¹S⁻¹ for holes and (9.3±1.5)×10⁻⁵ cm²V⁻¹s⁻¹ for electrons. The higher hole and electron mobility in PTT-L is consistent with the regioregularity of PTT-L. Charge carrier mobility is directly dependent on the regioregularity of polymers. This solid state polymerization could be valuable in a variety of applications, including pattern formation of NIR polymers.

Morphology

In order to investigate the morphology and packing of PTT-L and PTT-Ni polymers, grazing incidence wide angle X-ray scattering (GIWAXS) profiles of the polymer films were measured.

Polymer samples for GIWAXS measurements were spin-coated from chlorobenzene solutions onto a polished silicon wafer coated with PEDOT:PSS. The films were annealed at 120° C. in a glovebox for 30 minutes. The GIWAXS measurements were performed with a radiation wavelength 1.1354 Å and beam incident angle 0.13°.

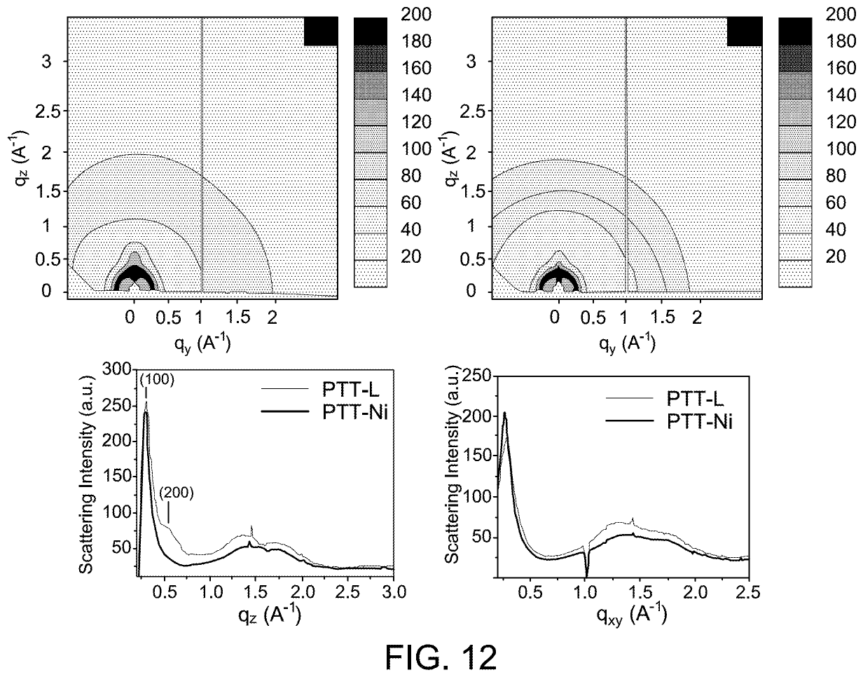

The results are shown in FIG. 12. General scattering profiles of both the polymers are very similar, demonstrating lamellar scattering peak at around 0.29 Å⁻¹ and p-p stacking peaks in the 1.4-1.7 Å region. Both the polymers are quite amorphous and lack preferential orientation. A lamellar peak at 0.29 Å⁻¹ is present in out-of-plane and in-plane directions for both the polymers. The same is true of the p-p stacking peaks. It should be noted that second order scattering (200) peak at 0.53 Å⁻¹ is observed in PTT-L's profile. This indicates that PTT-L has a more ordered structure than PTT-Ni which is consistent with PTT-L being more regio-regular.

Side Product Investigation

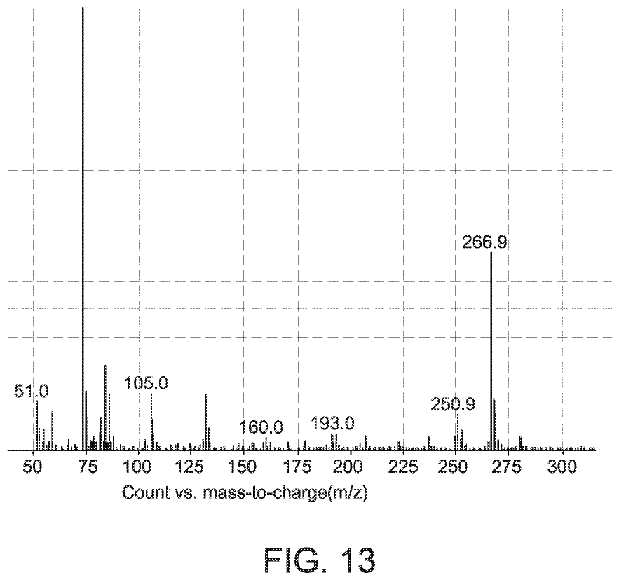

The photochemical polymerization method described in Example 1 generates a side product of HBr. This side product was initially observable because each time the PTT-L reaction vial was opened, a pressure was felt and considerable amounts of white gas came out from the vial. To further prove this side product, phenyltrivinylsilane was exposed to the side product to encourage a bromination reaction. Phenyltrivinylsilane (10 mg) was dissolved in 1 mL dry hexane in a sealed vial under N₂ protection, and 2 mL gas from a PTT-L reaction vial was transferred to this vial with a syringe. The gas from the PTT-L reaction vial was assumed to be HBr contaminated, so the formation of (2-bromoethyl)(phenyl)divinylsilane from phenyltrivinylsilane was expected. After 7 days, GC-MS was used to investigate the product. The spectrum is shown in FIG. 13. The peak 266.9 can be assigned to the monobrominated product (2-bromoethyl)(phenyl)divinylsilane. GC-MS (C₁₂H₁₅BrSi) m/z: calculated for 267.2, found as: 266.9.

Reaction Mechanism

A critical, yet accidental observation to understand the reaction mechanism was that only a short time exposure of visible room light was required to complete the reaction. A monomer sample briefly exposed to the light (for about 1 minute) before it was wrapped with aluminum foil and stored in a refrigerator was polymerized the next day. Without being bound by theory, the reaction mechanism is analyzed in detail to inform the scope of the monomers that may be polymerized according to the methods described herein.

Homo-polymerization of aromatic dihalide monomers involving different mechanisms and thermally activated solid state coupling of dihalothiophenes are well documented. Non-halothiophenes are known to undergo photoinduced stepwise polymerization with photolysis. Thiophene monomers can undergo oxidative polymerization (either electrochemically or chemically) to form polymers. With the present monobromo-thienothiophene compound, 2-ethylhexyl 6-bromothieno[3,4-b]thiophene-2-carboxylate, none of those mechanisms can explain the present observations.

Tables 3 and 4 show the reaction conditions and polymerization results, respectively, for the monomers reacted under a variety of conditions. These tables yield insights into the reaction mechanism.

TABLE 3
Monomers and reaction conditions.

| Entry | Monomer | Light | Gas | Reagents | Time |
|---|---|---|---|---|---|
| 1 | M1 | No | O₂ | — | 14 h |
| 2 | M1 | No | N₂ | — | 14 h |
| 3 | M1 | Yes | N₂ | | 10 min |
| 4 | M1 | Yes | O₂ | | 10 min |
| 5 | M1 | Yes | N₂ | 1-Hexanethiol | 14 h |
| 6 | M1 | No | N₂ | 1-Hexanethiol | 14 h |
| 7 | M1 | No | N₂ | AIBN (80° C.) | 14 h |
| 8 | M1 | No | N₂ | AIBN (60° C.) | 14 h |
| 9 | M1 | Yes | N₂ | Ethyl acrylate | 14 h |
| 10 | M1 | Yes | N₂ | 1,4- | 14 h |
| | | | | Benzoquinone | |
| 11 | M1 | Yes | N₂ | Et₃N | 14 h |
| 12 | M1 | No | O₂ | HBr | 14 h |
| 13 | M1 | No | O₂ | Br₂ | 10 min |
| 14 | M1 | Yes | O₂ | CHCl₃ | 3 days |
| 15 | M2 | Yes | O₂ | DCM | 10 min |
| 16 | 9 | Yes | O₂ | DCM | 14 h |
| 17 | 9 | No | O₂ | Br₂ | 10 min |
| 18 | 9 | No | O₂ | Br₂/DCM | 10 min |
| 19 | M1 | Yes | N₂ | TEMPO | 14 h |
| 20 | M1 | Yes | N₂ | TEMPO/Br₂ | 14 h |
| 21 | M3 | No | O₂ | | 14 h |
| 22 | M3 | No | N₂ | Br₂/DCM | 14 h |

All the new formed polymers are characterized with GPC against a polystyrene standard. M_{w} is weight-average molecular weight. Other than stated, all the control experiments were carried out at room temperature.

TABLE 4
Monomers and polymerization results.

| | | M_{w} | | |
|---|---|---|---|---|
| Entry | Monomer | (kg/mol) | PDI | Yield (%) |
| 1 | M1 | — | — | |
| 2 | M1 | — | — | |
| 3 | M1 | 5.23 | 1.17 | 95 |
| 4 | M1 | 3.37 | 1.04 | 94 |
| 5 | M1 | 3.74 | 1.03 | 95 |
| 6 | M1 | — | — | |
| 7 | M1 | 3.26 | 1.10 | 92 |
| 8 | M1 | 3.52 | 1.08 | 93 |
| 9 | M1 | 3.16 | 1.05 | 90 |
| 10 | M1 | — | — | |
| 11 | M1 | — | — | |
| 12 | M1 | — | — | |
| 13 | M1 | 3.30 | 1.02 | 93 |
| 14 | M1 | 3.68 | 1.10 | 94 |
| 15 | M2 | 3.31 | 1.03 | 96 |
| 16 | 9 | — | — | |
| 17 | 9 | 3.33 | 1.04 | 95 |
| 18 | 9 | 2.93 | 1.10 | 93 |
| 19 | M1 | | | |
| 20 | M1 | Oligomer | | |
| 21 | M3 | — | — | |
| 22 | M3 | — | — | |

All the new formed polymers are characterized with GPC against a polystyrene standard. M_{w} is weight-average molecular weight. Other than stated, all the control experiments were carried out at room temperature.

The four control experiments, shown in entries 1-4 of Tables 3 and 4, seem to support a photolytical cleavage step. Entries 1 and 2 show that the polymerization does not happen when the monomers are stored in the dark, while entries 3 and 4 showed that the polymerization occurs both in N₂ and O₂ when light is present. Entry 10 shows that the reaction does not occur in the presence of one equivalent of 1,4-benzoquinone (a well know radical inhibitor). Since quinone is an effective quencher for excited states, the photolytically cleavage of C—Br bond did not occur in this mixture.

In experiments 5 and 6, one equivalent of 1-hexanethiol was mixed with monomer M1. While the mixture in the dark (entry 6) was stable, it was sluggishly polymerized under light (entry 5), which indicated that the reaction is not a radical chain reaction since thiol compounds are known chain transfer agents in free radical reactions. While the polymerization in entry 3 completed within ten minutes, the initiation of the polymerization in entry 5 took 4 hours and completed overnight. These results indicate that the polymerization could not be a radical reaction since thiol compounds are known efficient agents for chain transfer in free radical reactions. In this reaction, one equivalent of thiol compound was used under conditions in which a radical polymerization cannot proceed. The slow polymerization can be related to the slow formation of a small amount of bromine molecules.

In entry 7, a mixture prepared from monomer M1 containing radical initiator, azobisisobutyronitrile (AIBN, 5% weight) was heated at 80° C. In entry 9, ethyl acrylate of 10 equivalents was mixed with monomer M1. It was found that monomer M1 polymerized under both conditions. MALDI-TOF studies showed that the end groups of polymer chains were the same as the polymers obtained in other conditions. Alkyl groups from AIBN and/or the incorporation of ethyl acrylate species in the formed polymers was not observed. Entry 8 indicated that the polymerization can also proceed with heating at the temperature (60° C.) that AIBN is stable. Based on these results, it can be concluded that a radical mechanism is not responsible for the polymerization.

The experiment in entry 11 indicated that triethylamine inhibited polymerization. This implies two things. First, trimethylamine is also a known quencher for certain photoexcited states, which can inhibit C—Br bond cleavage. Second, the HBr formed is important for polymerization. The experiment in entry 12 showed that the monomer did not undergo polymerization by adding HBr (initiator scale about 5%). However, polymerization did occur in the experiment (entry 13) when a small amount of bromine (initiator scale about 5%) was added to the monomer. Therefore, the bromine formed during the photolytic process is likely the origin for the polymerization. Further studies in the reaction conditions showed that the polymerization also occurred in solution state by dissolving the monomer M1 in CHCl₃ (10 mg/mL), although the reaction was much slower than that in the solid state (entry 14). While in solid state (entry 4) the reaction completed within ten minutes, the transparent solution started turning to yellow after 5 hours, and it took 3 days when the color changed to blue, indicating the formation of polymers.

Furthermore monomer M2, shown in Scheme 1, was synthesized and used in the experiment of entry 15, which was found to be similarly reactive towards photoinduced polymerization.

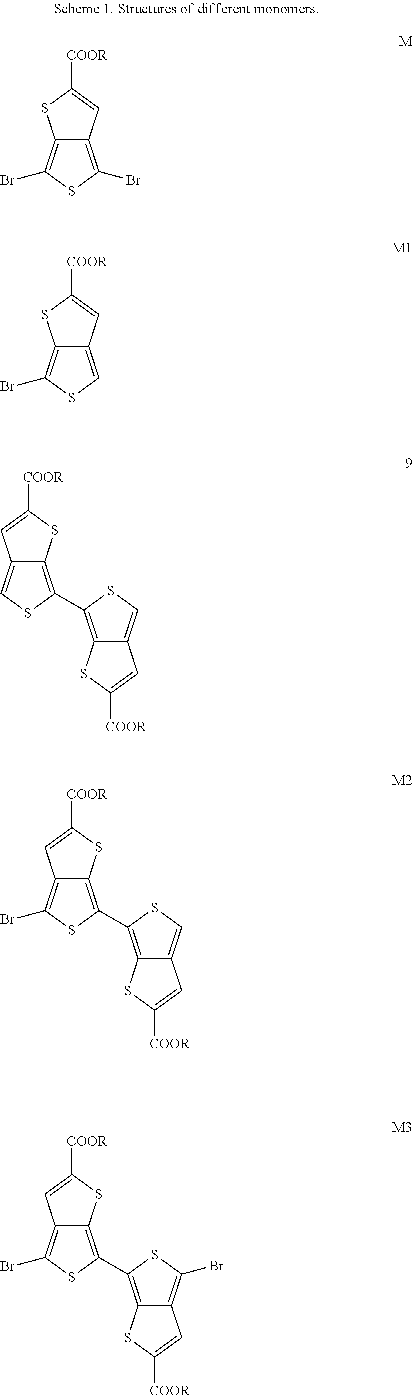

Three more experiments (entries 16, 17 and 18) offer further support to the hypothesis that bromine is the crucial source of polymerization initiator. The compound 9, shown in Scheme 1, was used as a monomer for these experiments. When it was exposed to light without adding any other reagents, it was shown to be stable. This experiment further excluded the possibility that radical coupling lead to the formation of polymers. When Br₂ was added, the polymerization proceeded in both solid and solution state.

In experiment entry 19, two equivalents of TEMPO (2,2,6,6-tetramethyl-1-piperidinyloxy) were mixed with the monomer and exposed to light under N₂. The color of the mixture did not change and MALDI-TOF experiments indicated that polymerization did not occur. With further addition of a small amounts (about 5%) of Br₂ (entry 20) to this mixture, oligomers was formed, thereby further indicating the Br₂ as an initiator. These experiments firmly proved the role of Br₂ and the role of other potential halogens.

The mechanistic function of bromine could possibly be due to charge transfer from electron rich monomer to form radical cations, which can then dimerize to form a dication. The dication will be converted into neutral dibromo-dithienothiophene (M3). However, this mechanism is in contradiction with observation that dibromo-dithienothiophene is stable both photochemically and toward bromine as shown in experiments (entries 21 and 22). This is also true for dibromothienothiophene (M). It seems that in these two compounds, the C—Br bonds are photochemically more stable than that in monomer M1.

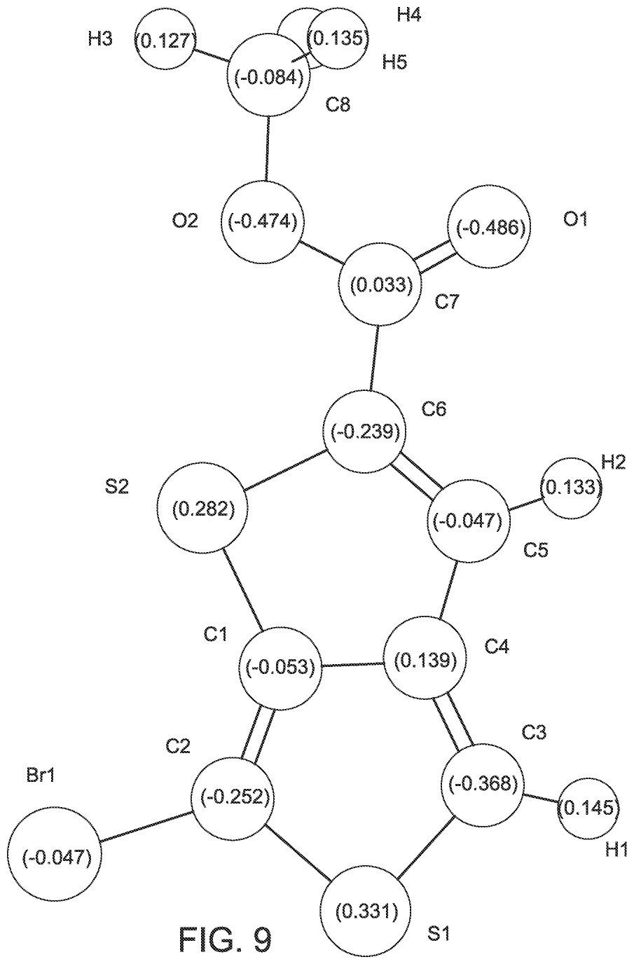

An important question for the cationic polymerization is which position is attacked by the reactive cation. Based at least on the data from experiments 15, 18, and 22, it is concluded that the C—H position is the reactive site that can be attacked by the cation while the C—Br side is not. DFT calculations of the monomer M1 further support this statement. The geometry optimization and energy calculations of M1 were conducted at B3LYP level of theory using 6-31G** basis set. Optimized geometry was used to calculate Mulliken charge distribution in the molecule. The results of the calculations, shown in Table 5, show that the carbon atom of a C—Br bond carries a Mulliken charge of −0.252 a.u. while the carbon atom of the C—H bond of monomer M1 carries a charge of −0.368 a.u. The model diagram and atomic numbering is shown in FIG. 9. More negative partial charge on this carbon atom will facilitate preferential attack by the cation.

TABLE 5
Calculated Mulliken charge on every atom of M1.

| Atom | Calculated Mulliken charge (a.u.) |
|---|---|
| C1 | −0.063 |
| C2 | −0.252 |
| C3 | −0.368 |
| C4 | −0.139 |
| C5 | −0.047 |
| C6 | −0.239 |
| C7 | −0.633 |
| C8 | −0.084 |
| H1 | 0.145 |
| H2 | 0.133 |
| H3 | 0.127 |
| H4 | 0.135 |
| H5 | 0.135 |
| O1 | −0.486 |
| O2 | −0.474 |
| Br1 | −0.047 |
| S1 | 0.331 |
| S2 | 0.282 |

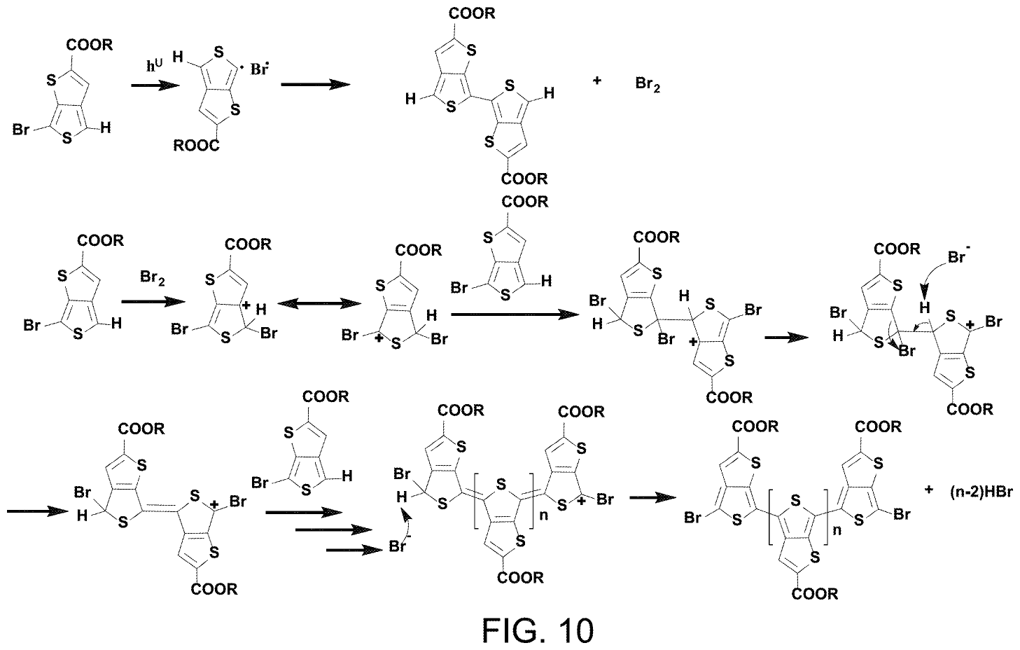

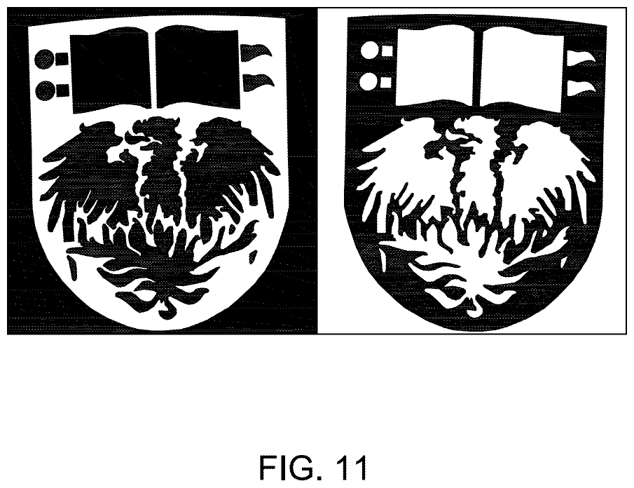

Based on all of the control experiments and DFT calculations, two possible mechanisms were proposed: photoinduced radical chain polymerization and photoinduced cationic polymerization. Without being bound by theory, after systematically designing and carrying out the foregoing series of experiments, and carefully investigating the structures and properties of the resulting polymers, it is believed that the most likely mechanism is a photoinduced chain-like cationic polycondensation (illustrated in FIG. 10).

In this mechanism, the C—Br bonds of monomers are first cleaved photolytically by absorbing light, followed by radical combination, and formation of a dimer and bromine molecules. The bromine electrophilically adds to the monomer and forms a living cation, a typical process for bromination in electron rich compounds. The initiated cation exists with its resonance structure, which is a living cation that can be stabilized by the lone pair electrons of the neighboring bromine and sulfur atoms. The newly formed cation attacks another monomer and passes the positive charge to the next monomer unit. This structure becomes non-conjugated and has a strong driving force to eliminate a HBr molecule to further form a cation with a quinoidal structure. This process can then repeat itself until the polymerization is stopped when the terminal proton is extracted by a bromine anion. The quinoidal structure then converts to a conjugated polymer.

This proposed mechanism is surprising and new for the synthesis of conjugated polymers based on aromatic monomers. In this mechanism, halogens, and bromine in particular, are the critical source of polymerization initiator. Negative partial charge on carbon atoms within the monomer will facilitate preferential attack by the cation. Based on this non-limiting proposed mechanism, any electron rich monohalogenated monomer may be polymerized according to the methods described herein.

The novel polymerization method described herein is a convenient and low-cost method of polymerization. Further, it is an in-situ polymerization and does not require external catalysts or reagents other than light.

Sample Applications

Patterning

A PMMA solution (30 mg/mL in ethyl acetate) was spin coated on a slide, and then annealed at 150° C. to modify the substrate. A solution of 2-ethylhexyl 6-bromothieno[3,4-b]thiophene-2-carboxylate (40 mg/mL in hexanes) was spin coated on the modified slide. At this stage, the slide was still transparent. A laser cut mask was put on the top of the coated slide. The slide was then exposed to visible light for 12 hours. It was observed that the color of the exposed part slowly changed from colorless/transparent to light yellow, yellow, light green and deep green. The mask was removed after 12 hours, and the slide was washed several times with methanol. Then the pattern was formed as showed in FIG. 11. The covered monomers were not polymerized but the exposed monomers were polymerized. The mask was laser cut and used a complicated design with many narrow gaps and sharp edges. Surprisingly, the resultant pattern showed relatively high resolution. This resolution may be further improved by using a straight light source in a dark environment and carefully preparing the monomer films.

Crosslinked Polymers

Oligomers of monohalogenated electron rich aromatic monomers can similarly be polymerized with exposure to light. In some embodiments, the oligomers are selected from the group consisting of dimers, trimers, and combinations thereof. In some embodiments, the produced polymers are crosslinked. In some embodiments, the produced polymers may be used in battery and water purification applications.

In some embodiments a dimer of a monohalogenated electron rich aromatic monomer is polymerized according to the methods described herein. In some embodiments the following dimer is polymerized according to the methods described herein.

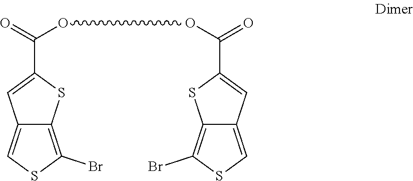 [SMILES: O=C(OOC(=O)c1cc2csc(Br)c2s1)c1cc2csc(Br)c2s1]

In some embodiments a trimer is formed from an amide formation reaction of the monohalogenated electron rich aromatic monomer. One sample embodiment is shown below. R₂₀ is selected from the group consisting of nitrogen, boron, phosphate, and trisubstituted cores.

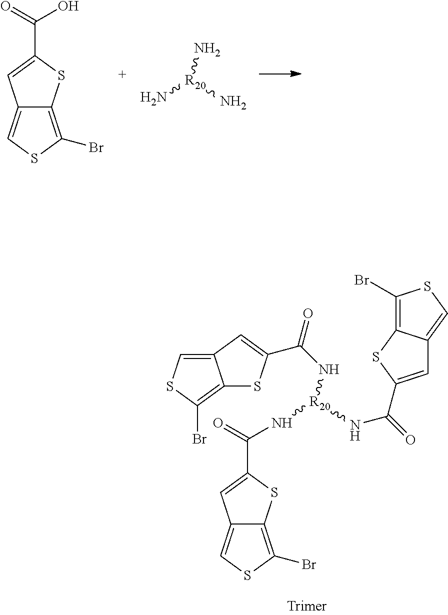

In some embodiments, this trimer is polymerized according to the methods described herein.

This written description uses examples to illustrate the present disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A method of preparing a regioregular conjugated polymer, the method comprising:
introducing a compound, wherein the compound is a monohalogenated electron rich aromatic monomer;
exposing the compound to light; and
polymerizing the compound.

2. A method of preparing a regioregular conjugated polymer, the method comprising:
introducing a compound, wherein the compound is an oligomer of a monohalogenated electron rich aromatic monomer;
exposing the compound to light; and
polymerizing the compound;
wherein the regioregular conjugated polymer is crosslinked.

3. The method of claim 1, wherein the method step of introducing the compound comprises introducing the compound as a solid reactant.

4. The method of claim 1, wherein the method step of exposing the compound to light comprises exposing the compound to ambient light.

5. The method of claim 1, wherein the method step of exposing the compound to light comprises exposing the compound to UV light.

6. The method of claim 1, wherein the method step of exposing the compound to light comprises exposing the compound to light for a duration in the range of about 1 minute to about 30 minutes.

7. The method of claim 1, wherein the method step of polymerizing the compound comprises polymerizing the compound at a temperature in the range of about 0° C. to about 15° C.

8. The method of claim 1, wherein the method step of polymerizing the compound comprises polymerizing the compound at a temperature in the range of about 15° C. to about 35° C.

9. The method of claim 1, wherein the method step of polymerizing the compound comprises polymerizing the compound in the absence of external reagents.

10. The method of claim 1, wherein the monohalogenated electron rich aromatic monomer comprises at least 10 π electrons.

11. The method of claim 1, wherein the monohalogenated electron rich aromatic monomer comprises a fused bicyclic aromatic group.

12. The method of claim 1, wherein the monohalogenated electron rich aromatic monomer is a compound of Formula I, wherein 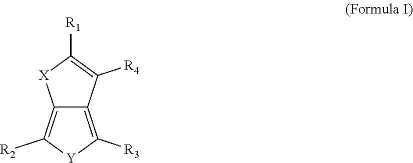
each of X and Y are independently selected from the group consisting of nitrogen, sulfur, phosphorous, and oxygen;
R₁ is selected from the group consisting of alkyl, halogenated alkyl, ester, ether, ketone, cyano, thiol, and sulfonyl;
each of R₂-R₄ is independently selected from the group consisting of hydrogen and halogen;
and
at least one of R₂-R₄ is a halogen.

13. The method of claim 1, wherein the monohalogenated electron rich aromatic monomer is a compound of Formula II, wherein 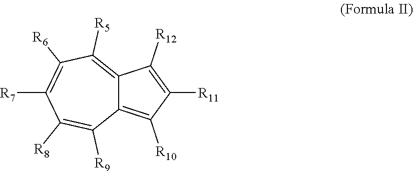
each of R₅-R₁₂ is independently selected from the group consisting of hydrogen and halogen;
and
wherein at least one of R₅-R₁₂ is a halogen.

14. The method of claim 1, wherein the monohalogenated electron rich aromatic monomer is selected from the group consisting of 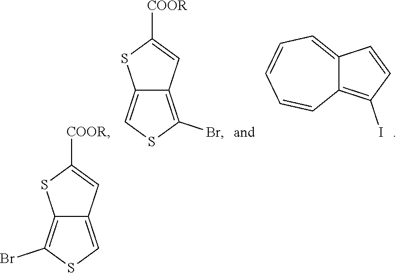
wherein R is selected from the group consisting of linear alkyl and branched alkyl.

15. The method of claim 1, wherein the monohalogenated electron rich aromatic monomer is selected from the group consisting of

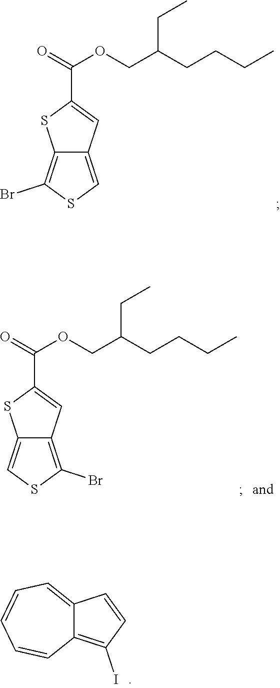 [SMILES: CCCCC(CC)COC(=O)c1cc2csc(Br)c2s1 ; CCCCC(CC)COC(=O)c1cc2c(Br)scc2s1 ; Ic1ccc2cccccc1-2]

16. The method of claim 2, wherein the oligomer of a monohalogenated electron rich aromatic monomer is a dimer or a trimer of the monohalogenated electron rich aromatic monomer.

17. The method of claim 1, wherein the method further comprises introducing a second compound selected from the group consisting of a monohalogenated electron rich aromatic monomer and an oligomer of a monohalogenated electron rich aromatic monomer before the method step of exposing the compound to light.

18. The method of claim 1, wherein the regioregular conjugated polymer is selected from the group consisting of regioregular polythienothiophene and regioregular polyazulene.

19. A method of patterning, the method comprising
spin coating on a surface a compound selected from the group consisting of a monohalogenated electron rich aromatic monomer and an oligomer of a monohalogenated electron rich aromatic monomer;
covering the surface with a pattern mask;
exposing the pattern mask to light; and
polymerizing the compound not covered by the pattern mask.

20. The method of claim 19, wherein the method further comprises removing the non-polymerized compound covered by the pattern mask.
